(19) United States
(12) Patent Application Publication
(10) Pub. No.: US 2014/0360576 A1
(43) Pub. Date: Dec. 11, 2014

(54) Intrinsically Semitransparent Solar Cell And Method Of Controlling Transmitted Color Spectrum

(71) Applicant: Lucintech, Inc., Toledo, OH (US)

(72) Inventors: Victor V. Plotnikov, Toledo, OH (US); Chad W Carter, Toledo, OH (US); John M. Stayancho, Marblehead, OH (US); Alvin D. Compaan, Holland, OH (US)

(21) Appl. No.: 14/374,336

(22) PCT Filed: Jan. 25, 2013
(86) PCT No.: PCT/US13/23139

§ 371 Date: Jul. 24, 2014

Related U.S. Application Data
(60) Provisional application No. 61/590,599, filed on Jan. 25, 2012.

(51) Int. Cl. H01L 31/052; H01L 31/0232; H01L 31/18

(52) U.S. Cl. CPC H01L 31/0528; H01L 31/1884; H01L 31/02327
USPC 136/257; 438/70; 136/256

(57) ABSTRACT

A structural element is described to control the color of light transmitted and reflected from an intrinsically semitransparent photovoltaic cell and/or module for use with a PV window and methods for fabricating the same. Color control elements are described that will 1) control or shift the color spectrum of light transmitted through the PV window, 2) control or shift the color spectrum of light reflected from the outside of the window, and 3) control or shift the color spectrum of light reflected from the inside of the PV window.

### CROSS REFERENCE TO RELATED APPLICATION

This application is based upon and claims the benefit of U.S. Provisional Patent Application No. 61/590,599; filed Jan. 25, 2012.

### FIELD OF THE INVENTION

The present invention relates generally to photovoltaic cells (PV) and the detailed layer structure thereof. More specifically, the present invention relates to the structure of a thin-film PV cell that is intrinsically semitransparent and the method of making such a device including control of the transmitted light color or spectrum and control of the reflected light color or spectrum.

### BACKGROUND OF THE INVENTION

The vast majority of photovoltaic devices or solar cells are fully opaque so that essentially all light incident on the cell is absorbed by the cell or module. Maximizing the light absorption will maximize the power generated by the solar cell. However, in some applications it is desired to use the PV device in an arrangement that allows some of the light to pass through the device, such as in a window, skylight, sunroof or canopy. There are a number of module structures in which some light transmission has been obtained by spacing the cells such that light passes between individual cells in a module (e.g., wafer silicon modules or copper-indium-gallium-diselenide (CIGS) cells on metal foil coupons) to provide some averaged light transmission. There are other structures that use thin-film PV in which some of the PV coating has been removed, such as by laser scribing or chemical etching. These solutions have the significant disadvantage of yielding a spatially non-uniform light transmission which is often undesirable.

There are some other thin-film PV materials that offer partial light transmission without such spacing of cells or selective removal. These include organic PV (small molecule or polymer) and dye sensitized solar cells (DSSC) which have relatively narrow absorption bands that absorb strongly in some spectral regions and weakly in others. This yields light transmission that is highly colored and also results in poor PV efficiency because only a narrow band of the visible spectrum is absorbed. Some other thin-film PV materials such as amorphous silicon (also called thin-film silicon) may transmit light but generally have low sunlight to electrical power conversion efficiencies of about 4 to 6% and poor transmitted light spectra with a reddish tint. It is desirable to have a solar cell that is semitransparent without the limitations of the prior semitransparent solar cells.

### SUMMARY OF THE INVENTION

The present invention describes three structures and methods of fabricating thin-film solar cells that modify the appearance of photovoltaic window insulating glass unit (PV IGU) and are illustrated for the case of one thin-film cell or module, namely one based on ultra-thin layers of cadmium sulfide (CdS) and cadmium telluride (CdTe) or their alloys with other group II and group VI elements. One structure and method controls the appearance or color of the transmitted light, the second structure and method controls the amount and appearance of the light reflected from the outside of the PV IGU, and the third structure and method controls the amount and appearance of light reflected from the inside of the PV IGU.

The present invention first describes structure and methods of controlling the spectrum of light transmitted through a thin-film cell or module. This cell or module may be based on ultra-thin layers of cadmium sulfide and cadmium telluride together with a front transparent contact layer and a back transparent contact layer. However, the methods described in this invention are applicable to cells and modules based on other thin-film PV materials, such as organic PV and thin-film silicon PV (CIGS).

This invention first describes a structure and method of controlling the transmitted light spectrum either by adding a component after the PV IGU that absorbs or reflects certain selected wavelength components, or by incorporating additional layers into the cell or module that absorb or reflect certain selected wavelength components.

The second part of the present invention describes a structure and method of controlling the light spectrum reflected from the outside of the PV IGU, that is, from the exterior of a building or vehicle.

The third part of the present invention describes a structure and method of controlling the amount of light and the light spectrum reflected from the inside of the PV IGU, that is, from the interior of a building or vehicle

The structures and methods described herein are applicable to ultra-thin film CdTe cells and modules and are demonstrated thereon. However, they are also applicable to other semitransparent PV cells and modules such as, but not limited to those fabricated from thin-film silicon, copper indium gallium diselenide and related materials, organic materials, and dye-sensitized solar cells.

The present invention relates generally to PV cells and methods of fabrication thereof. More particularly, this invention relates to a PV cell having an absorber layer sufficiently thin but uniform and pinhole free so as to be semitransparent but still to have high efficiency as a solar cell or module.

The present invention discloses the structure of, and the method of manufacturing of, such a semitransparent PV IGU that incorporates elements for control of the amount and color spectrum of transmitted light, for control of the amount and color spectrum of light reflected from the outside of the module, and control of the amount and color spectrum of light reflected from the inside of the PV IGU.

The present invention relates to an earlier invention, “INTRINSICALLY SEMITRANSPARENT SOLAR CELL AND METHOD OF MAKING SAME,” and describes improvements thereof that control and balance the color spectrum of the transmitted or reflected light to achieve and enhance desired effects. Improvements proposed here also lead to improved current generation in the cell and therefore higher efficiency. One commonly desired effect is that the transmitted light color be as neutral as possible, that is, that the color of the transmitted light be approximately the same as that of the incident light, as perceived by the human eye. This is frequently referred to as the transmitting object or window having “neutral density.” This means the light intensity is attenuated but otherwise composed of the same or similar spectral components.

Other objects and advantages of the present invention will become apparent to those skilled in the art upon a review of the following detailed description of the preferred embodiments and the accompanying drawings.

### BRIEF DESCRIPTION OF THE DRAWINGS

FIG. 1 is a perspective side elevational view of a layer structure of a standard thin-film CdTe solar cell without transmitted light color spectrum control features.

FIG. 2a is a perspective side elevational view of a structure to change the light color spectrum transmitted through the PV IGU structure by selective absorption.

FIGS. 2b and 2c are perspective side elevational views of the invention of FIG. 1 at the back of the outside glass lite and at the front side of the interior lite.

FIG. 3 is a perspective side elevational view of a structure to change the light color spectrum transmitted through the PV IGU structure by selective reflection.

FIG. 4 is a graph of the photopic response of the normal human eye showing the highest responsivity at about 560 nm and the typical range of good response from about 450 nm to about 650 nm. In addition, the transmission of an ultra-thin CdTe solar cell structure is shown with transmission through an absorptive element as depicted in FIG. 2.

FIG. 5 is a perspective side elevational view of a layer structure to change the light color reflected from the outside of the PV IGU structure.

FIG. 6a is a perspective side elevational view of a layer structure to change the intensity and color of light reflected from the interior side of the PV IGU incorporating a multilayer dielectric coating that is non-absorptive.

FIG. 6b is a perspective side elevational view of a layer structure to change the intensity and color of light reflected from the interior side of the PV IGU glass or polymer film controlling color by selective absorption

FIG. 7a is a graph of the reflectance of a 15 nm gold film on glass (left axis) and the photopic response of the human eye (right axis).

FIG. 7b is a graph of the reflectance of a 15 nm gold film on glass after depositing four transparent dielectric layers consisting of 100 nm of SiO2, 88 nm of TiO2, 100 nm of SiO2, and 88 nm of TiO2. The photopic response of the human eye is shown on the right axis.

FIG. 8a is a graph of the reflectance of a 15 nm gold layer modified by the addition of two dielectric layers consisting of 140 nm of SiO2 and 60 nm of TiO2. The photopic response of the human eye is shown on the right axis.

FIG. 8b is a graph of the reflectance of a 15 nm gold layer modified by the addition of 140 nm of SiO2 and 70 nm of TiO2. The photopic response of the human eye is shown on the right axis.

FIG. 9 is a graph of the reflectance of a five layer structure on glass without a gold layer. The five layer structure consists of CdS/SiO2/CdS/SiO2/CdS with thicknesses in nanometers of 75/120/75/120/75 respectively. The photopic response of the human eye is shown on the right axis.

FIG. 10 is a perspective side elevational view of an IGU that incorporates the invention of FIG. 1.

### DETAILED DESCRIPTION OF THE PREFERRED EMBODIMENT(S)

This invention first describes structures and methods for controlling the transmitted light spectrum either by adding a separate structural component to the PV cell or module that absorbs or reflects certain selected wavelength components, or by incorporating additional layers into the cell or module structure itself that absorb or reflect certain selected wavelength components.

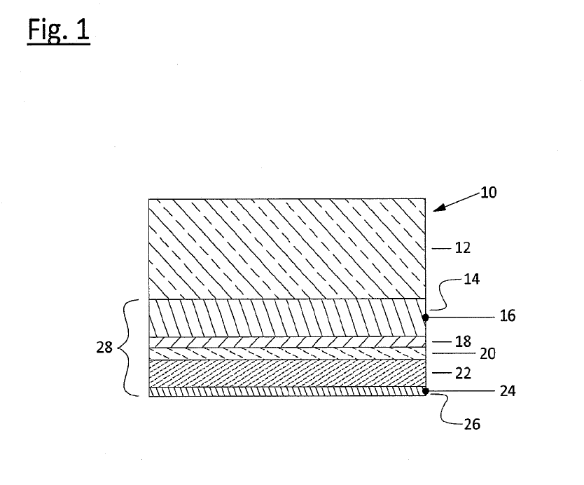

The differences are best understood by referring to the drawings, FIGS. 1-3.

FIG. 1 illustrates the structure of a thin-film CdTe solar cell on a substrate. This has all of the previously identified layers shown in U.S. Pat. No. 7,141,863 of Compaan and Gupta but in addition shows a high resistivity transparent (HRT) layer as has been discussed in the literature. Following Compaan and Gupta, the addition of the HRT layer, and the improvements of thinner CdTe and a transparent back contact incorporated in “INTRINSICALLY SEMITRANSPARENT SOLAR CELL AND METHOD OF MAKING SAME”, the present invention describes further improvements obtained by inserting additional elements or layers to the basic cell structure to enhance color rendition, transparency, and improve the efficiency.

Referring to FIG. 1 for the structure of the photovoltaic cell 10, we refer now to the final layer of the solar cell or module. In the embodiment of the invention shown in FIG. 1, the device is shown in the superstrate configuration, which means that the substrate material used during the deposition becomes the top (superstrate) window, and the various layers are deposited in order starting with the substrate layer 12. In other configurations the substrate material used during the deposition becomes the bottom layers, and the various layers are deposited in order starting with this substrate material. Therefore, for purposes of this invention, the term “substrate layer” means either a substrate or a superstrate.

In a preferred embodiment of the invention, the transparent electrode layer 14 is any one or more of the group zinc oxide (ZnO), zinc sulfide (ZnS), cadmium oxide (CdO), tin oxide doped with fluorine (SnO₂:F), indium oxide doped with tin (In₂O₃:Sn), gallium oxide (Ga₂O₃), combinations of the preceding and other well known compositions of transparent conductive coatings. Most preferably, the transparent electrode layer 14 is ZnO. Also, preferably, the transparent electrode layer 14, whether ZnO, ZnS or CdO, is doped with a Group III element to form an n-type semiconducting layer. Most preferably, the transparent electrode layer 14 is ZnO doped with aluminum (AZO) or SnO doped with fluorine (FTO). Layer 18 is a high resistivity transparent (HRT) layer which may be any one of the group specified for layer 14 but without doping so that the electrical resistance is high. Preferably this HRT layer is ZnO or SnO₂ with thickness of about 25 nm to about 200 nm; most preferably with a thickness from about 50 nm to about 100 nm.

The first of two primary semiconductor layers is an n-type semiconductor layer 20. In a preferred embodiment of the invention this n-type semiconductor layer 20 is cadmium sulfide (CdS). The second primary semiconductor layer is a p-type semiconductor 22, which is preferably cadmium telluride (CdTe) or an alloy of CdTe. Numerous other semiconductor layers can be used for either of these two primary semiconductor layers, as will be appreciated by those skilled in the art. Examples of possible semiconductors are any photovoltaic device including but not limited to: thin film technologies such as CdTe, CIGS, copper zinc tin sulfide (CZTS) a-Si; mono- and poly-crystalline silicon; dye-sensitized, polymer or organic solar cells with any visual light transparency achieved by either modifying chemical composition, reducing the thickness of the active layer or back contact, or partial removal of the active layer or the back contact by laser ablation or other patterning method. It is to be understood that an intrinsic semiconductor layer, not shown, can be disposed between the n-type semiconductor layer and the p-type semiconductor layer in conjunction with the present invention.

A back conductive electrode (BC) layer 26, which is the second of the two ohmic contacts or electrodes for the photovoltaic cell 10. The BC layer 26 contains a conductive lead 24 for conducting current through the electric circuit, not shown. Typically, the conductive electrode layer is made of nickel, titanium, chromium, aluminum, gold, molybdenum oxide or some other conductive material. Optionally, an additional protective or buffer layer of zinc telluride, not shown, can be positioned between the back contact layer 26 and the cadmium telluride semiconductor layer 22 to facilitate hole (positive charge carrier) transport from the cadmium telluride layer 22 to the BC layer 26 and to protect the cadmium telluride layer 22 form foreign contamination by migration. Also, it is to be understood that the layer of back buffer material and the BC layer 26 can sometimes be combined into a single layer, not shown. To handle both functions in a single contacting layer, the single layer would have to have an electrical conductivity substantially equivalent to that of the BC layer 26, and yet still would have to be capable of making good transition to the CdTe semiconductor layer.

The photovoltaic cell 10 includes a substrate layer 12, which preferably is a glass substrate 12. Other transparent materials, such as polyimides, can be used as an alternative for the glass substrate 12. A layer of a transparent conductive material, such as a transparent electrode layer 14, is applied to the glass layer 12. The transparent electrode layer 14 forms one of the two ohmic contacts or electrodes for the photovoltaic cell 10, and contains a conductive lead 16 for conducting current through an electric circuit, not shown. The transparent electrode layers are also sometimes referred to as a transparent conductive oxide (TCO), although some useful materials for this purpose are not oxides.

This BC layer 26 must have suitable electronic characteristics as required for a back contact to CdTe and it must be transparent. Among the required electronic properties are that the work function must be a good match to the electron affinity of the CdTe layer 22 such that the positive charge carriers (holes) can flow readily into the BC. The embodiment of BC preferred in the prototype window unit that is shown in FIGS. 1-3 is a very thin layer of Cu and a thin layer of Au followed by the deposition of a transparent conductor such as ZnO:Al or indium tin oxide (ITO). These layer thicknesses are preferred to be in the ranges of: for Cu: 0.2 nm to 3 nm; for Au: 3 nm to 30 nm; and for the transparent conducting oxide (e.g., AZO or ITO): 500 to 1500 nm. This final BC layer most preferably should be adjusted in thickness such that optical interference effects result in light wavelengths reflected back into the CdTe that are most effective in power generation. For example, this includes the near infrared region with little or no eye sensitivity, roughly in the range from about 600 nm to 850 nm. And the thickness should most preferably also be adjusted so that light in the more sensitive range of the eye should have minimal reflection from the back contact, e.g., from 450 to 600 nm. Similar considerations can apply to adjustments of the thicknesses of all the layers. The goal is to maximize the absorption of light in the most sensitive power-generating range of the CdTe cell and otherwise maximize the transmission of light visible to the eye. Thickness adjustments can also be used to help balance the color neutrality of the transmitted light from the exterior 50.

The photovoltaic cell 10 includes a thin-film CdTe solar cell 28. The thin-film CdTe solar cell 28 is the combination of the transparent electrode layer 14, conductive lead 16, HRT layer 18, semiconductor layers 20 and 22, conductive lead 24, and BC layer 26.

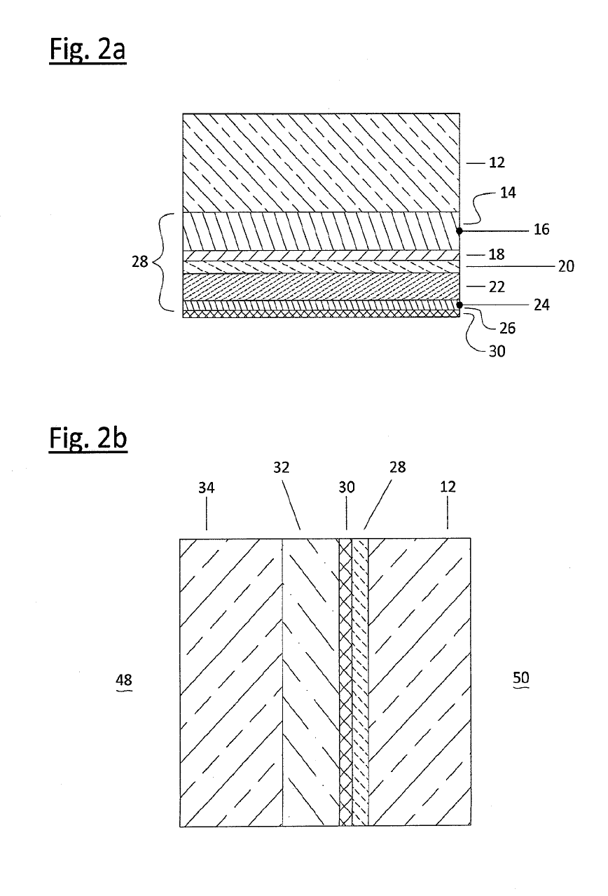

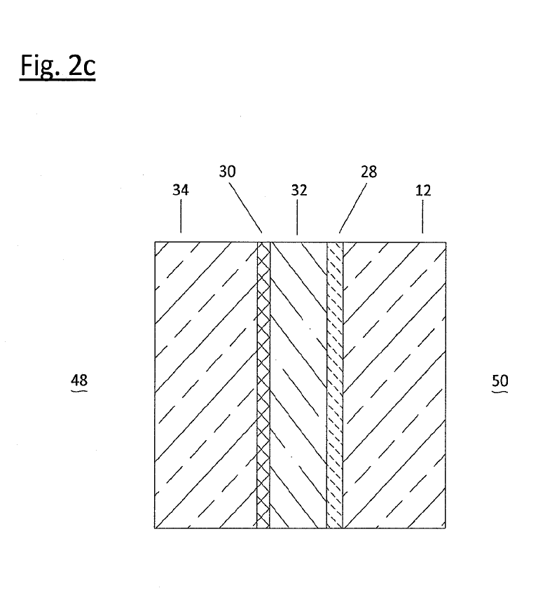

FIG. 2a illustrates a color selective absorbing element 30 which can be applied as a separate layer to the thin-film CdTe solar cell 28, most easily after the cell is completed, i.e., after the back contact 26 is applied. The structure of the color selective absorbing element 30 functions to change the light color spectrum transmitted through the PV IGU structure by selective absorption. A color selective absorbing element 30 layer can be added directly onto the BC 26 (FIG. 2a) or as a separate structural element below/after the BC. FIG. 2b shows a color selective absorbing element 30 and polymer laminate 32 in a laminated glass/glass structure. In this embodiment the thin-film CdTe solar cell 28 is layered on the side of the glass substrate 12 that faces the interior of the structure 48. The polymer laminate 32 is layered on the side of the glass substrate 34 which faces the exterior of the structure 50. The color selective absorbing element 30 is layered in between the thin-film CdTe solar cell 28 and the polymer laminate 32. The color selective absorbing element 30 is a color absorbing filter that is usually made of glass. It should be appreciated, however, that the filter can be made from materials other than glass, such as polymer sheets, as long as the filter selectively absorbs the desired portion of the color spectrum. Examples of commercially available polymer sheets are custom colored Vanceva® PVB interlayers manufactured by Saflex®. But the absorbing element may also be incorporated as part of a separate element of the window structure.

A color glass/polymer sheet, or color selective absorbing element 30 can be attached to the thin-film CdTe solar cell 28. In FIG. 2c the color selective absorbing element 30 is positioned on the side of the second lite (pane) 34 facing the exterior 50. The color selective absorbing element 30 and the second lite 34, together with the outer PV window element comprises the PV IGU.

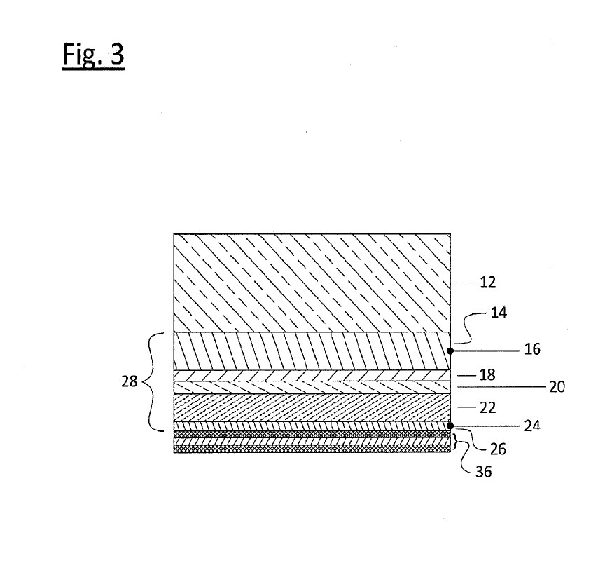

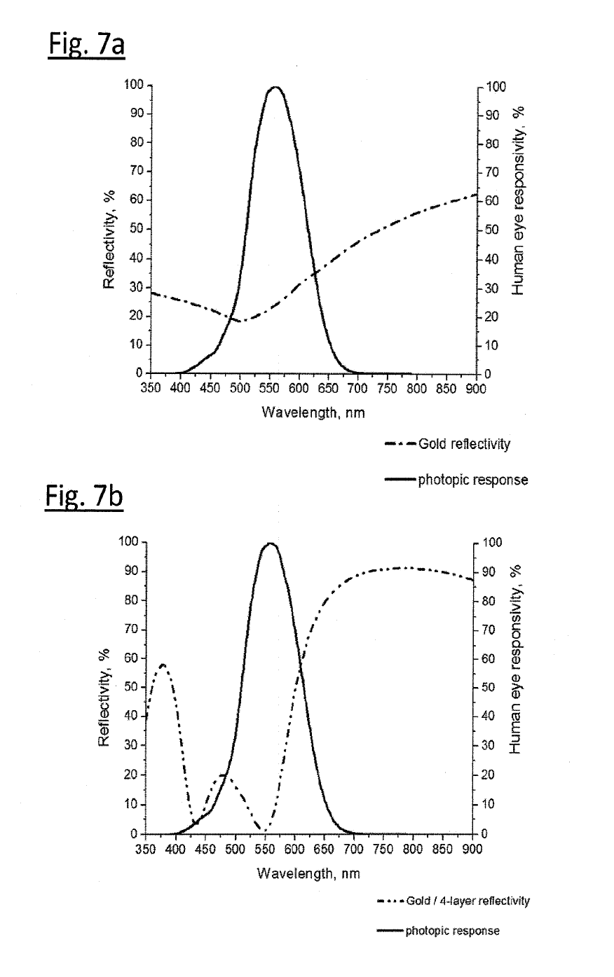

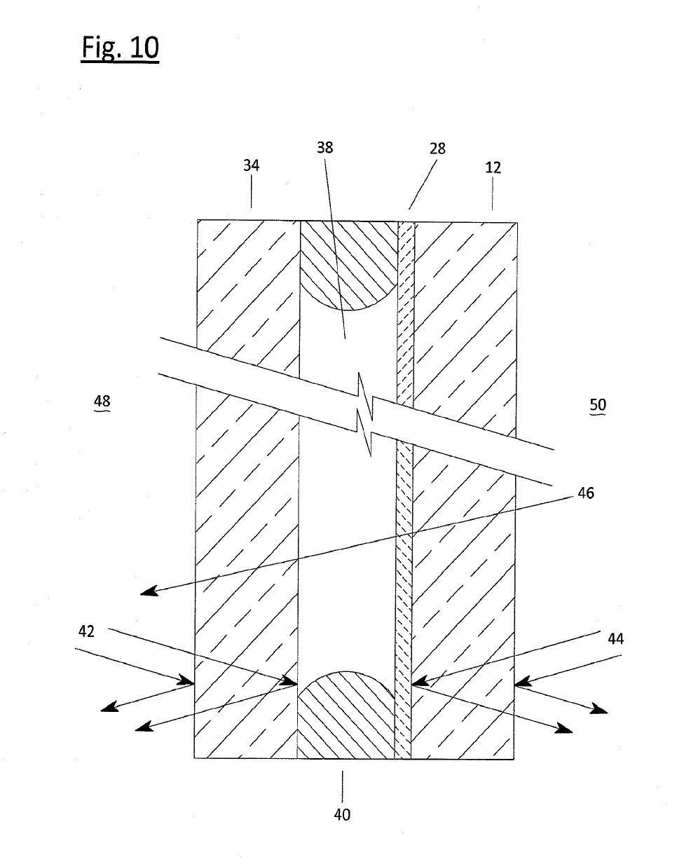

FIG. 3 illustrates a color selective reflective element 36 which can be applied as a separate layer or layers to the thin-film CdTe solar cell 28, most easily after the cell is completed, i.e., after the back contact 26 is applied. It may also be applied as an integral part of the back contact. The structure of the color selective reflective element 36 functions to change the light color spectrum transmitted through the PV IGU by selective reflection. Spectral selectivity is controlled by the index of refraction, thickness of the layers, and number of layers. The color selective reflective element 36 can be a reflective filter or a dielectric layer. Color selective reflective elements are frequently used in more than one layer as shown in FIG. 3. The color selective reflective elements 36 are non-absorbent, but reflect light with the desired indices of refraction. But the color selective reflective element 36 of FIG. 3 may also be incorporated as part of a separate element of the PV IGU structure. For example, the color selective reflective element 36 described in FIG. 3 may be incorporated as part of a second lite of glass that, together with the outer PV window element, comprise a PV IGU. In this case the color selective reflective element 36 may be applied either to the inside or outside of the second lite of glass. “Inside” refers to the interior of the PV IGU which is normally a sealed and argon-filled space 38 (FIG. 10). “Outside” refers to the side facing the interior 48 of a building, vehicle or other structure. The operation of such multilayer dielectric elements is illustrated in FIGS. 7, 8, and 9 below.

Note that this structure in FIG. 3 is typically a multilayer stack of dielectric materials that are themselves transparent. This stack may consist of only two layers or have these two layers repeated a number of times. This stack may be placed on or deposited onto the BC or the stack may be part of a second glass lite or part of a polymer sheet behind the BC. It is also possible that this stack be incorporated as part of the BC or placed between the CdTe and the BC but in such cases the layers must have sufficient electrical conductivity to carry the photogenerated current of the PV IGU.

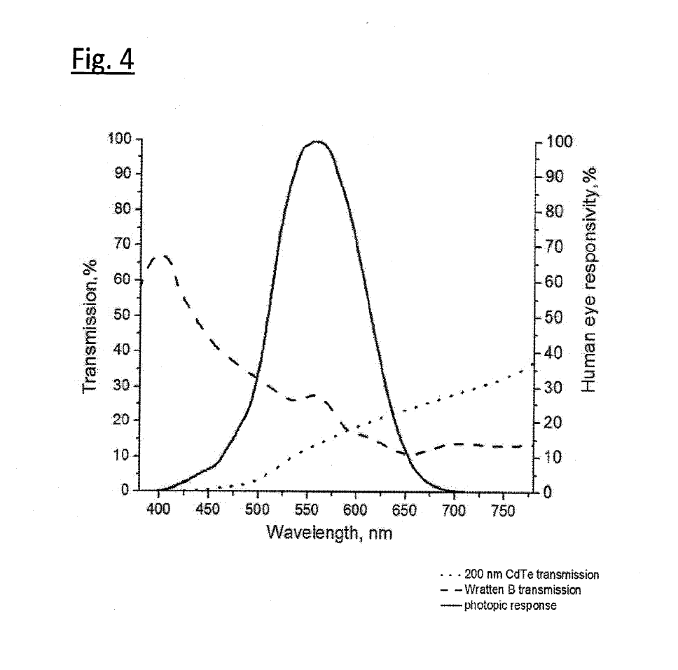

The function of the color selective elements 30 and 36 described in FIGS. 2 and 3 (whether absorptive or reflective) as it relates to perceived color is described with the help of the graphs of FIG. 4. FIG. 4 shows the photopic response of the normal human eye (solid curve, referenced to the right axis), showing the maximum responsivity at about 560 nm corresponding to the yellow region of the visible light spectrum, with much lower responsivity in the blue and green region from about 400 nm to about 520 nm and also much lower responsivity in the red region from about 600 nm to 700 nm. The dotted curve in FIG. 4, referenced to the left axis with a maximum of 1 (100%), shows the light transmission through a 200 nm layer of CdTe. Less light is transmitted in the blue/green region and more in the red region which will produce a bronze hue in the transmitted light. The dashed curve in FIG. 4, also referenced to the left axis, shows the light transmission through an absorptive glass filter commonly known as “Wratten B”. This filter transmission is higher in the short wavelengths and appears blue. Light which is transmitted through both the CdTe layer and the Wratten B filter appears neutral or “grey” and illustrates one type of color selective element of this invention.

Comparing the function of the absorptive with the reflective element for color shifting of the transmitted light, one sees that there is little difference, in principle, between light transmitted through the PV structure using an absorptive or a reflective element that has the same transmission curve. So, as far as the colors perceived by a human viewing the transmitted light, there is little to prefer absorptive over reflective elements.

However, since a color selective absorbing element absorbs the solar radiation it will tend to heat up whereas a reflective element will not. We have described these color shifting elements as being placed behind the PV device structure because it is important to maximize the light absorption in the PV device structure to maximize the electricity generation, otherwise the color selective absorbing element could, in principle, be placed in front of the PV device structure. More importantly, the color selective reflecting element 36 is to be preferred (when placed behind the PV device structure) because it reflects the light back through the PV layers and therefore will naturally tend to enhance the efficiency of the PV window in converting sunlight to electricity. Therefore, the reflective element is to be preferred over the absorptive, although there may be differences in ease of construction or in cost that may cause the absorptive element to be preferred.

We have demonstrated the advantage of the color selective reflecting element 36 by measuring the current generated in an ultra-thin CdTe cell with and without a reflective element placed behind the cell, similar to the sketch of FIG. 3. The color selective reflecting element 36 placed against the back contact 26 behind the PV device structure increased the electrical current and efficiency by 5-10% over the current and efficiency attained without the reflective element. This example is for illustrative purposes only to show the functional advantage of the reflective element in shifting the transmitted color at the same time as increasing the performance of the solar cell device.

The illustrative example provided in the paragraph above, used the reflective element behind the back contact coating. Functionally, it would be advantageous to place the reflective element immediately after the CdTe 22 layer and before the back contact or to make the reflective layers be part of the back contact itself. This might be done by using an appropriate metal with suitable reflection spectrum. (Gold films have optical characteristics with some suitable properties.) Most ideally, one may use a multilayer dielectric coating to achieve the optimum spectral reflectivity for this element, which might also have suitable electrical characteristics. These electrical characteristics would need to include the electrical conductivity and the interfacial properties to match the CdTe interface with suitable work function or electron affinity to provide good electrical transport of holes from the CdTe into the back contact and, if possible, electron reflection from the back contact structure (as described in the prior invention “INTRINSICALLY SEMITRANSPARENT SOLAR CELL AND METHOD OF MAKING SAME.”)

FIG. 7a shows the reflection from a thin layer of gold on glass with thickness typical of a back contact to CdTe. Gold reflects strongly in the deep red at about 700-800 nm but less strongly at 500 nm (blue-green to the eye). Thus a 15 nm layer of gold will appear as blue-green in transmitted light.

By applying silicon dioxide (SiO2) and titanium dioxide (TiO2) in a four-layer coating of transparent materials (SiO2/TiO2/SiO2/TiO2) with respective thicknesses of 100/88/100/88 nm, as shown in FIG. 7b the reflectivity can be reduced to zero at the peak of the eye sensitivity at 550 nm and reduced below the gold reflectivity from about 400 to about 575 nm, thus increasing the blue and green light transmission. Simultaneously, the structure will have much higher reflectivity from 600 nm to 850 nm. The light wavelengths in this region will be reflected back into the solar cell and increase the solar cell efficiency by increasing the current.

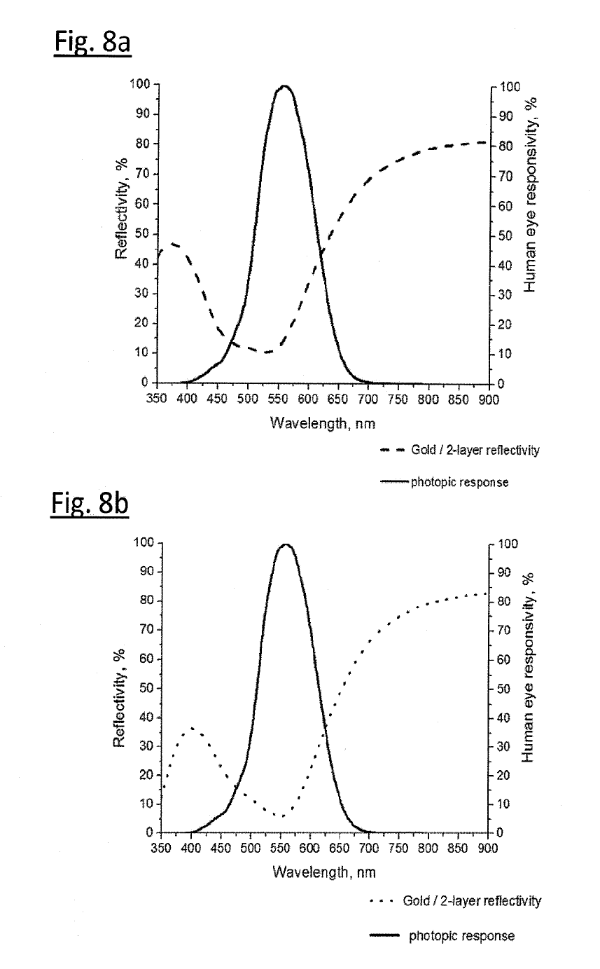

Two other examples are shown in FIGS. 8a and 8b. These examples illustrate the changes that can be achieved by adding only two layers after the 15 nm thick gold layer. FIG. 8a shows the results for 140 nm of SiO2 and 60 nm of TiO2. FIG. 8b shows the results for 140 nm of SiO2 and 70 nm of TiO2, illustrating the capability of tailoring the transmission by adjusting the dielectric layer thickness, in this case the TiO2, after the gold back contact layer.

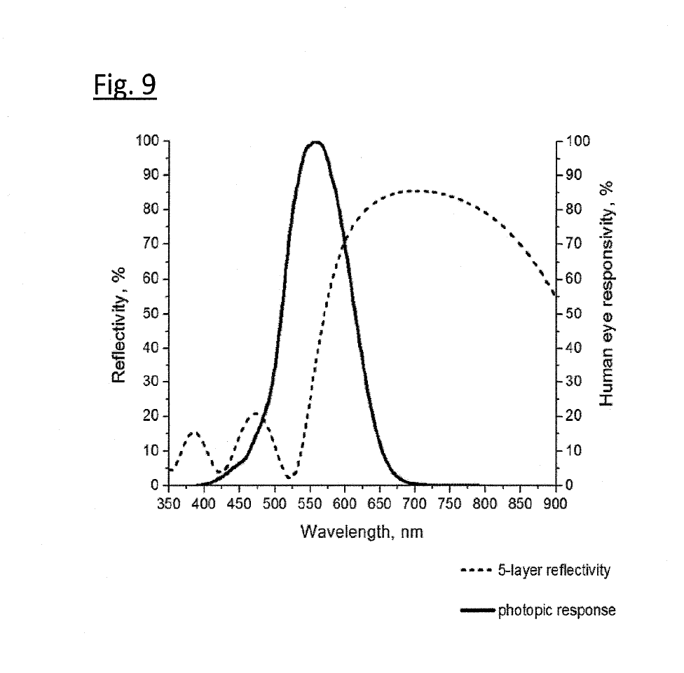

FIG. 9 illustrates that there is a variety of materials that can be used to achieve these color selective effects. This example, shows a five layer coating (no gold) using CdS/SiO2/CdS/SiO2/CdS with respective thicknesses of (75/150/75/150/75 nm). This example shows that similar results are possible with a variety of materials.

The choice of materials used for the color selective reflective elements in the examples provided in FIGS. 4, 7, 8, and 9 are for illustration only and it should be clear to anyone skilled in the art that a wide variety of materials can be used for these elements. SiO2 is chosen as a low index of refraction dielectric material and TiO2 is chosen as a high index of refraction dielectric material. CdS is chosen also as a high index of refraction material and is generally considered to be a semiconductor rather than a dielectric. In these examples, the metal, gold, and the semiconductor, CdS, were chosen for their electronic and optical properties as suitable for contacting with CdTe.

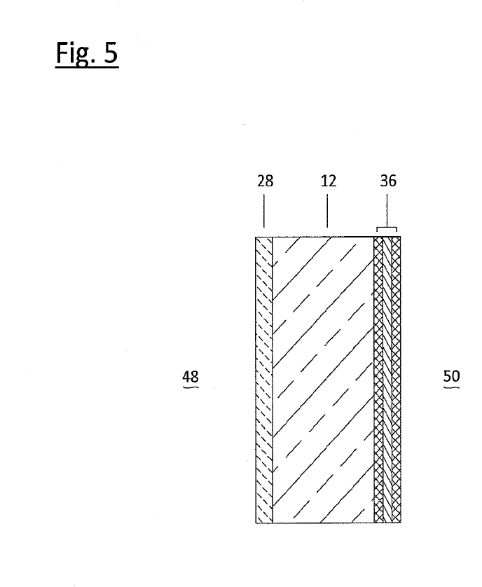

The second part of the present invention describes a structure and method of controlling the light spectrum reflected from the outside of the PV window is shown in FIG. 5. FIG. 5 shows a layer structure of component to change the light color reflected from the outside of the PV window structure. FIG. 5 shows the color selective reflecting element 36 layered on the side of the lite substrate 12, which faces the exterior 50. The thin-film CdTe solar cell 28 is layered on the side of the first lite, substrate 12, which faces the interior 48. Normally this coating will be applied to the side of the glass opposite the PV coating. For architectural aesthetics it is appropriate to control the light reflected from a window, including a PV window, from the outside. Since the CdTe coating on the inside of the outer panel of the IGU appears from the glass side to be essentially colorless and black, it is relatively easy to control the appearance of the window in reflected light. There is little need to balance the color spectrum as there is in the transmitted light. Thus, the PV window can be left uncoated and the natural reflection from glass would typically reflect the sky. In clear sky conditions, this would give a blue appearance which is usually desired by architects. However this appearance could easily be enhanced or shifted by applying a reflective coating such as the reflective element layers previously described in FIG. 3 following application methods in common practice in the industry. Thus, the current materials and methods could easily be adapted to the PV windows. Here it is important that the deposition process for the CdTe solar cells takes place at temperatures of about 250° C. with a subsequent heat treatment near 370° C. These temperatures may be compatible with the exterior color control coatings being applied before the PV coatings are applied. This is particularly true of the sputter deposition process which is the preferred method of fabricating the ultra-thin CdS/CdTe layers of the PV coating. Specifically, the outside reflective coatings could be applied during the glass manufacturing process or at least before the beginning of the PV coating application.

Typically low-E glass coatings often have a “color suppression” layer which provides some control of the light reflected from this lite. What is proposed here is a coating of one or more layers that is particularly optimized for use with the CdS/CdTe PV coating of this invention.

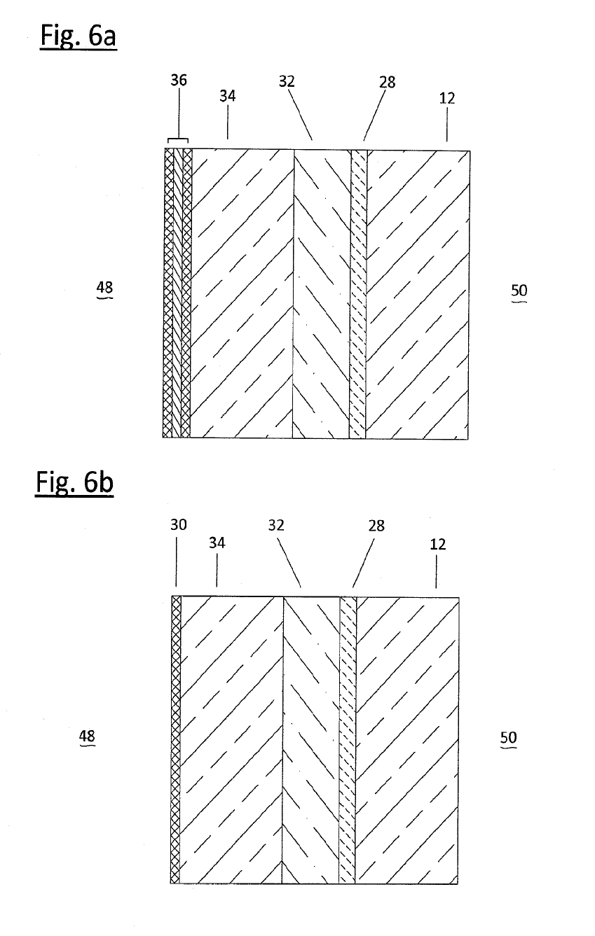

The third part of the present invention describes a method of controlling the amount of light and the light spectrum reflected from the inside of the PV window is shown in FIG. 6a. FIG. 6a shows a layer structure of two types of components placed after the PV structure of FIG. 1 to change the intensity and color of light reflected from the inside of the PV window. FIG. 6a depicts the color selective reflecting element 36 on the side of the second lite, substrate 34, which faces the interior 48. The thin-film CdTe solar cell 28 is layered on the side of the first lite, 12, which faces the interior 48. The lamination layer is in between the thin-film CdTe solar cell 28 and the second lite 34. FIG. 6a creates reflected color and intensity produced by multilayer dielectric coating that is non-absorptive. FIG. 6b creates reflected color and intensity produced by selective absorption. It may be desirable to control independently the appearance of the window from the interior of the building or vehicle or other structure. FIG. 6b depicts the color selective absorbing element 30 on the side of the second lite 34 which faces the exterior 48. The thin-film CdTe solar cell 28 is layered on the side of the first lite 12 which face the interior 48. The lamination layer 32 is in between the thin-film CdTe solar cell 28 and the second lite 34. In the process of applying a back contact/back reflector structure to the PV window, the resulting appearance may be highly reflective or mirror-like and may have an undesirable, colored appearance. In such cases, it is possible to apply an additional coating or multilayer coating structure to the back of the PV window. Alternatively, it is possible to place an appropriate reflective or absorptive coating on the innermost pane of the IGU. One possible coating that might be applied to the outer surface (back contact) of the PV window coating is an extremely thin absorptive coating such as CdTe. We have found that 50 or 100 nm of CdTe can achieve strong suppression of the back side reflection without causing significant decrease in the light transmission through the structure. FIG. 6a shows reflective filter layers such as previously described in FIG. 3 and FIG. 6b shows a color selective absorbing element 30 such as previously described in FIG. 2a-2c. This is an example only; many other absorptive coatings could be applied to accomplish this objective.

FIG. 10 illustrates the color control achieved by the instant invention. Three types of color control are achieved: 1) color and amount of light transmitted from the outside (exterior) of the window unit to the interior; 2) color and amount of light reflected from the exterior of the window unit; and 3) color and amount of light reflected from the interior of the window unit.

FIG. 10 depicts a typical IGU with opposing lites of glass, 12 and 34, creating an inert gas-filled cavity 38, and sealed by an edge seal, 40. FIG. 10 shows the (3) different ways in which light interacts with the PV IGU: transmitted light 46, light that is reflected off the exterior surface 44, and light from inside the room reflecting off the interior surface 42. The PV IGU of FIG. 10 will appear differently from different perspectives: as viewed from the exterior of a building or the interior of the room. PV windows using CdS/CdTe layers will typically use a monolithic integration scheme for electrically isolating strips of the thin film into cells approximately 1 cm wide and the width or length of the window. Monolithic integration is an important part of fabricating a large-area module that is suitable for window applications. The additional color shifting elements will typically be fully compatible with these three-scribe interconnects that provide monolithic series connection as described in the previous provisional patent application, “INTRINSICALLY SEMITRANSPARENT SOLAR CELL AND METHOD OF MAKING SAME.”

The above detailed description of the present invention is given for explanatory purposes. It will be apparent to those skilled in the art that numerous changes and modifications can be made without departing from the scope of the invention. Accordingly, the whole of the foregoing description is to be construed in an illustrative and not a limitative sense, the scope of the invention being defined solely by the appended claims.

We claim:

1. A thin-film photovoltaic cell having an element for color control of the light transmitted through, or reflected from, a thin-film photovoltaic cell (PV) window that is intrinsically semitransparent that generates solar electricity and transmits visible light, the thin-film photovoltaic cell comprising:
a transparent substrate or superstrate layer, such as glass or polymer such as a polyimide;
a transparent conducting layer, such as a transparent conducting oxide;
a high electrical resistivity transparent layer;
a semiconducting structure with one or more n-p junctions or one or more n-i-p junctions that absorb a wide range of light wavelengths and generate current and voltage (electrical power); and
a transparent back contact (BC) structure that transmits visible light and conducts current;
a color control element having selective absorbing and/or reflecting properties.

2. The photovoltaic cell of claim 1 wherein the color control element has selective absorption properties and is a discrete structural element behind the PV window.

3. The photovoltaic cell of claim 1 wherein the color control element has selective absorption properties and is a layer that is integral to the PV window coating and applied to the back contact.

4. The photovoltaic cell of claim 1 wherein the color control element has selective absorption properties and is more than one layer that is integral to the PV window coating and an integral part of the back contact.

5. The photovoltaic cell of claim 1 wherein the color control element has selective reflective properties and is a discrete structural element behind the PV window.

6. The photovoltaic cell of claim 1 wherein the color control element has selective reflective properties and is a layer that is integral to the PV window coating and the back contact.

7. The photovoltaic cell of claim 1 wherein the color control element has selective reflective properties and is more than one layer that is integral to the PV window coating and is an integral part of the back contact.

8. The photovoltaic cell of claim 1 wherein, the PV window structure controls the color of light reflected from the outside of the PV window element.

9. The photovoltaic cell according to claim 14 wherein the external reflected color control element is a coating on the outside of a first glass lite.

10. The photovoltaic cell according to claim 8 wherein the external reflected color control element is a coating between the interior surface of the first glass lite, between the glass and the transparent conductor.

11. The photovoltaic cell of claim 1 incorporating the reflection suppression and/or color control element, for the PV window structure, that controls the amount of and color of light reflected from the interior side of the PV window structure such as an Insulating Glass Unit or IGU, that is, the side facing the inside of a room or vehicle.

12. The photovoltaic cell of claim 11 wherein the interior reflection suppression and/or color control element is added as a separate structural element including the inner lite of the IGU, or attached to the inner lite of the IGU.

13. The photovoltaic cell of claim 11 wherein the reflection suppression and/or color control element is added as an integral layer to the back side of the PV window after the back contact/back reflector layer is formed.

14. A method for fabricating a thin-film photovoltaic cell having an element for color control of the light transmitted through, or reflected from, a thin-film photovoltaic cell window that is intrinsically semitransparent that generates solar electricity and transmits visible light, the solar cell having a transparent conducting layer, a high electrical resisting transparent layer, a semiconducting layer and a transparent back contact, the thin-film photovoltaic cell comprising:
positioning a color control element having selective absorption and/or reflective properties in the photovoltaic cell.

15. The method of claim 14 in which the element has selective absorption properties and is applied as a discrete structural element behind the PV window coating.

16. The method of claim 14 in which the element has selective absorption properties and is applied as a layer that is integral to the PV window coating and applied to the back contact.

17. The method of claim 14 in which the element has selective absorption properties and is applied as more than one layer that is integral to the PV window coating and applied as an integral part of the back contact.

18. The method of claim 14 in which the element has selective reflective properties and is applied as a discrete structural element behind the PV window.

19. The method of claim 14 in which the element has selective reflective properties and is applied as a layer that is integral to the PV window coating and applied to the back contact.

20. The method of claim 14 in which the element has selective reflective properties and is applied as more than one layer that is integral to the PV window coating and applied as an integral part of the back contact.
